(19) United States
(12) Patent Application Publication
(10) Pub. No.: US 2004/0130019 A1
(43) Pub. Date: Jul. 8, 2004

(54) Light source system with sealed light emitting diode recesses

(76) Inventor: Mi-Chien Chen, Tu-chen (TW)

Correspondence Address: WEI TE CHUNG, FOXCONN INTERNATIONAL, INC., 1650 MEMOREX DRIVE, SANTA CLARA, CA, 95050, US

(21) Appl. No.: 10/739,572

(22) Filed: Dec. 17, 2003

(30) Foreign Application Priority Data
Dec. 17, 2002 (TW) 91220455

(51) Int. Cl. H01L 23/34

(52) U.S. Cl. 257/723

(57) ABSTRACT

A light source system (2) includes a light guide plate (27), a plurality of LEDs (23), same amount of sealing blocks (25), same amount of fluorescent layers (24), same amount of conductive wirings (22), cathodes (21) and anodes (26). Each of the LED sealing blocks is disposed corresponding to one LED for fixing it from outside. Each pair of cathode and anode is connected to one of the LEDs through a conducted wiring to provide working current. Each of the fluorescent layers is disposed on the recesses respectively for converting the light emitted from the LEDs to fluorescence. The light source system is easy to manufacture and has a high efficiency of utilization of the LEDs.

### BACKGROUND OF THE INVENTION

1. Field of the Invention

The present invention relates to a light source system used in devices such as liquid crystal displays (LCDs), and particularly to a light source system which has a plurality of light emitting diodes (LEDs).

2. Description of Prior Art

FIG. 5 shows a conventional light source system 1 as disclosed in Taiwan Pat. No. 417,937. The light source system 1 includes a plurality of LEDs 11, a printed circuit board 12, and a light guide plate 13. The LEDs 11 are bonded to the printed circuit board 12 by a plurality of binding blocks 15, which can be made of transparent plastic or synthetic resin. The light guide plate 13 defines a plurality of grooves 14 in one side thereof, each of grooves 14 corresponding to one LED 11. In assembly, the LEDs 11 are received in the grooves 14. In use, the light beams emitted by the LEDs 11 are emitted into the light guide plate 13, and subsequently emitted from a light emitting surface of the light guide plate 13.

Such a structure has two disadvantages. One disadvantage is the absorption of light emitted from each LED 11 by its binding block 15. The absorption reduces the efficiency of utilization of light of the LEDs 11, and diminishes the brightness of light emitted from the light guide plate 13. The other disadvantage is the relatively complicated manufacturing process for the light source system 1. Workers must first attach the LEDs 11 onto the printed circuit board 12, and then attach the printed circuit board 12 to the light guide plate 13. This takes a relatively long time and retards production efficiency.

It is desired to provide a light source system which overcomes the above-described problems.

### SUMMARY OF THE INVENTION

An object of the present invention is to provide a light source system which can be easily manufactured.

Another object of the present invention is to provide a light source system yielding output light having high brightness.

To achieve the above objects, a light source system of a preferred embodiment of the present invention comprises a light guide plate, a plurality of LEDs and a plurality of LED sealing blocks. A plurality of recesses is defined in a side of the light guide plate, and each contains a LED respectively. The LED sealing blocks fix the LED from outside.

Because the LEDs are directly received in the recesses and sealed by the sealing blocks, it is simpler to manufacture the light source system compared with the above-described prior art. In addition, the sealing blocks fix the LEDs from outside thereof. Such sealing means does not interfere with light emitted from the LEDs. Therefore the efficiency of utilization of the LEDs is enhanced.

Other objects, advantages, and novel features of the present invention will become more apparent from the following detailed description when taken in conjunction with the accompanying drawings; in which:

### BRIEF DESCRIPTION OF THE DRAWINGS

FIG. 1 is a cross-sectional view of a light source system according to a first embodiment of the present invention;

FIG. 2 is a cross-sectional view of a light source system according to a second embodiment of the present invention;

FIG. 3 is an isometric view of a kind of light guide plate used in the light source system of the present invention;

FIG. 4 is an isometric view of another kind of light guide plate used in the light source system of the present invention;

FIG. 5 is a three dimensional, exploded view of a conventional light source system.

### DETAILED DESCRIPTION OF THE INVENTION

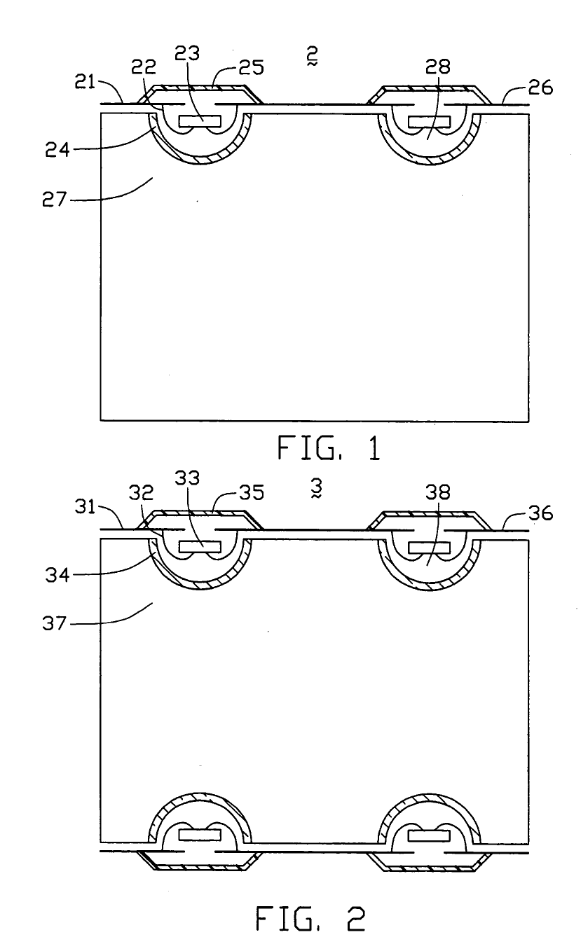

Referring to FIG. 1, a light source system 2 according to the first embodiment of the present invention comprises a light guide plate 27, a pair of LEDs 23, a pair of LED sealing blocks 25, a pair of fluorescent layers 24, a pair of conductive wirings 22, a pair of cathodes 21 and a pair of anodes 26.

A pair of recesses 28 is defined in an incident side of the light guide plate 27, for containing the LEDs 23. Each of the LED sealing blocks 25 corresponds to one of the LEDs 23, for sealing the LED 23 from outside contamination. Each cathode 21 is paired with a corresponding one of the anodes 26. Each cathode 21 and anode 26 combination is connected to a corresponding one of the LEDs 23 through a corresponding one of the conductive wirings 22, to provide working current to the LED 23. Each of the fluorescent layers 24 is disposed on the light guide plate 27 in a corresponding one of the recesses 28, for converting light emitted from the LEDs 23 to fluorescence.

Referring to FIG. 2, a light source system 3 according to the second embodiment of the present invention comprises a light guide plate 37 and a plurality of LEDs 33. A plurality of recesses 38 is symmetrically defined in each of two opposite sides of the light guide plate 37, for containing the LEDs 33. Like the light source system 2, for each LED 33 the light source system 3 has an LED sealing block 35, a fluorescent layer 34, a conductive wiring 32, a cathode 31 and an anode 36.

The symmetric configuration allows the light source system 3 to emit light more uniformly for enhanced performance.

Other measures can also be employed for the light source system 2, 3. For example, diffusing dots can be formed on the light guide plate 27, 37. Further, the light guide plate 27, 37 can have a rectangular side profile or be wedge-shaped, and can be made of a transparent material such as synthetic resin or glass.

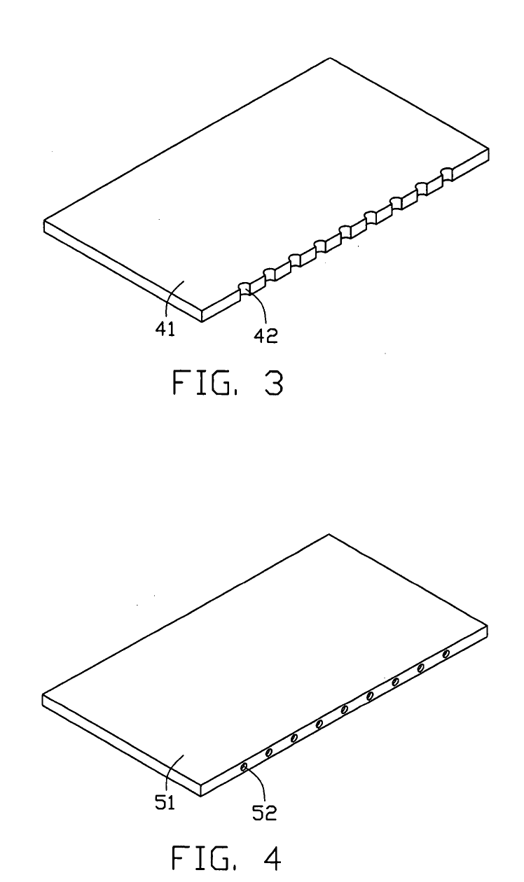

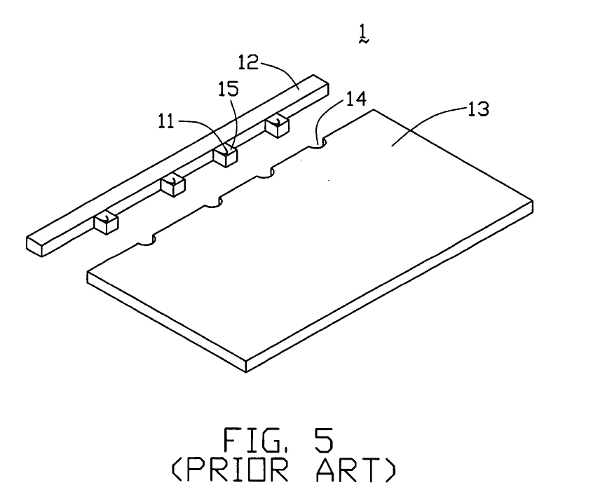

The recesses 28, 38 defined in the light guide plate 27, 37 can be arch-shaped, semi-cylindrical, arcuate, semi-elliptical, square, or rectangular. Alternatively, the recesses 28, 38 may be blind holes. Referring to FIG. 3, a light guide plate 41 used in a light source system of the present invention defines a plurality of semi-cylindrical grooves 42. Referring to FIG. 4, a light guide plate 51 used in a light source system of the present invention defines a plurality of cylindrical holes 52.

The recesses 28, 38 can be formed by injection molding, die-casting or machining. The number and positions of the recesses 28, 38 can be configured according to the required number and positions of the LEDs 23, 33.

The fluorescent layers 24, 34 are provided on corresponding surfaces of the light guide plate 27, 37 in the recesses 28, 38. To obtain a desired chroma of fluorescence, the fluorescent layers can contain the needed combination of known fluorescent materials. The select fluorescent materials can be solidified by heating to form the fluorescent layers 24, 34. Light beams emitted by the LEDs 23, 33 are converted by the fluorescent layers 24, 34 to a fluorescence having the desired hue and saturation. The fluorescence is emitted into the light guide plate 27, 37 and subsequently emitted from a light emitting surface of the light guide plate 27, 37.

Because the LEDs 23, 33 are directly received in the recesses 28, 38 and sealed by the sealing blocks 25, 35, it is simpler to manufacture the light source system 2, 3 compared with the above-described prior art. In addition, the sealing blocks 25, 35 fix the LEDs 23, 33 from outside thereof. Such sealing means does not interfere with light emitted from the LEDs 23, 33. Therefore the efficiency of utilization of the LEDs 23, 33 is enhanced. Furthermore, to obtain other illumination effects, such as a suitable chroma, the fluorescent layers 24, 34 can be constituted accordingly.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

1. A light source system, comprising:
a light guide plate;
a plurality of light emitting diodes (LEDs); and
a plurality of LED sealing blocks;
wherein a plurality of recesses is defined in at least one of opposite sides of the light guide plate, and each of the recesses contains a corresponding LED sealed by a corresponding LED sealing block.

2. The light source system as claimed in claim 1, further comprising a plurality of fluorescent layers disposed on the light guide plate in the recesses.

3. The light source system as claimed in claim 2, further comprising a cathode and an anode connecting with each of the LEDs, for supplying working current.

4. The light source system as claimed in claim 3, wherein the recesses are grooves.

5. The light source system as claimed in claim 4, wherein the light guide plate has a rectangular side profile.

6. The light source system as claimed in claim 4, wherein the light guide plate is wedge-shaped.

7. The light source system as claimed in claim 4, further comprising diffusing dots provided on the light guide plate.

8. The light source system as claimed in claim 3, wherein the recesses are holes.

9. The light source system as claimed in claim 8, wherein the light guide plate has a rectangular side profile.

10. The light source system as claimed in claim 9, wherein the light guide plate is wedge-shaped.

11. The light source system as claimed in claim 9, further comprising diffusing dots provided on the light guide plate.

12. A light source system comprising:
a light guide plate defining an incident side thereof;
a plurality of light emitting sources located around said incident side and activated by electricity;
a plurality of electrodes spatially extending along said incident side and mechanically and electrically connected to the corresponding light emitting sources, respectively; and
a plurality of sealing blocks fixing the light emitting sources and the associated electrodes, respectively, from an outside of said light guide plate.

13. The light source system as claimed in claim 12, wherein each of said light emitting sources is located in a corresponding recess formed in the incident side.

14. The light sources system as claimed in claim 13, wherein a fluorescent layer is applied to a surface of a region of the light guide plate facing to the recess.

15. A light source system comprising:
a light guide plate defining an incident side thereof;
a plurality of recesses formed in and along said incident side;
a plurality of light emitting sources respectively located in the corresponding recesses and activated by electricity; and
a plurality of sealing blocks bonding the light emitting sources, respectively, from an outside of said light guide plate.

16. The light source system as claimed in claim 15, wherein a fluorescent layer is applied to a surface of a region of said light guide plate facing said recess.
